(19) United States
(12) Patent Application Publication
(10) Pub. No.: US 2026/0140145 A1
(43) Pub. Date: May 21, 2026

(54) Power-Electronic Circuit Arrangement And Method For Arranging A Current Measuring Resistor In Such A Circuit Arrangement

(71) Applicant: Schaeffler Technologies AG & Co. KG, Herzogenaurach (DE)

(72) Inventors: Uwe Krella, Gersthofen (DE); Matthias Duchrau, Heroldsberg (DE); Markus Kolodziej, Hochstadt am Main (DE); Andreas Greif, Neukirchen/Brand (DE)

(73) Assignee: Schaeffler Technologies AG & Co. KG, Herzogenaurach (DE)

(21) Appl. No.: 19/121,594

(22) PCT Filed: Oct. 26, 2023
(86) PCT No.: PCT/EP2023/079879

§ 371 Date: Apr. 16, 2025

(30) Foreign Application Priority Data
Oct. 28, 2022 (DE) 10 2022 211 474.4

(51) Int. Cl. G01R 15/14

(52) U.S. Cl. CPC G01R 15/146

(57) ABSTRACT

A power-electronic circuit arrangement may include: a plate-shaped circuit carrier with an electrically insulating substrate and a conductor track arrangement, and one or more power-electronic components electrically contacted by the conductor track arrangement; a bus bar to conduct an electric current from or to a conductor track of the conductor track arrangement; and a current measuring resistor connecting the bus bar and the conductor track to enable the current to be measured by tapping a measuring voltage dropping across the current measuring resistor. The bus bar has a surface portion located at a vertical distance from a flat side of the conductor track arrangement and oriented substantially parallel to the flat side. The current measuring resistor is interposed between said surface portion of the bus bar and a surface portion of the conductor track of the conductor track arrangement and is physically and electrically connected to these surface portions.

### CROSS-REFERENCE TO RELATED APPLICATIONS

This application is a U.S. National Stage Application of International Application No. PCT/EP 2023/079879 filed Oct. 26, 2023, which designates the United States of America, and claims priority to DE Application No. 10 2022 211 474.4 filed Oct. 28, 2022, the contents of which are hereby incorporated by reference in their entirety.

### TECHNICAL FIELD

The present disclosure relates to power-electronic circuits Various embodiments of the teachings herein include systems and/or methods for arranging a current measuring resistor in such a circuit arrangement.

### BACKGROUND

An circuit arrangement has: a plate-shaped circuit carrier, which has an electrically insulating substrate and, on a flat side of the substrate, a conductor track arrangement and one or more power-electronic components electrically contacted by means of the conductor track arrangement, a bus bar for conducting an electric current from or to a conductor track of the conductor track arrangement of the circuit carrier, and a current measuring resistor (“shunt”) via which the bus bar and the conductor track in question are electrically connected to one another in order to enable the current to be measured by tapping a measuring voltage which drops across the current measuring resistor. Circuit arrangements of this kind are known in many embodiments from the prior art. One example of this is an inverter for the pulsed power supply of an electric machine, e.g., an electric motor in an electric or hybrid vehicle.

In practice, the following requirements are often placed on such a circuit arrangement: low-inductance and low-impedance electrical connection of the current measuring resistor, low thermal resistance between current measuring resistor and environment or current measuring resistor and a heat sink, small installation space, low-cost assembly and connection technology (ACT). There is still room for improvement in the prior art, particularly with regard to meeting the aforementioned requirements. The concepts known from the prior art for the construction or manufacture of a generic circuit arrangement generally involve conflicting objectives that are difficult to resolve.

According to a known concept, for example, a bus bar is provided with a first portion and a second portion, wherein the first portion runs in a straight line parallel to the circuit carrier at a vertical distance from the conductor track arrangement and the second portion continues with curves up to the vertical level of the conductor track arrangement, wherein a gap is provided between the two portions, in which the current measuring resistor is arranged and welded on both sides to said portions of the bus bar. The disadvantage here is, for example, that there is often insufficient heat dissipation from the current measuring resistor into the environment or a heat sink.

### SUMMARY

Teachings of the present disclosure may eliminate or at least mitigate the above-mentioned problems in a power-electronic circuit arrangement of the type mentioned at the outset. Various embodiments of the teachings herein include circuit arrangements which enable a good electrical and thermal connection of the current measuring resistor with simultaneously low-cost assembly and connection technology. For example, some embodiments of the teachings herein include a power-electronic circuit arrangement (10), having a plate-shaped circuit carrier (12), which has an electrically insulating substrate (14) and, on a flat side (15) of the substrate (14), a conductor track arrangement (16) and one or more power-electronic components (18) electrically contacted by means of the conductor track arrangement (16), a bus bar (20) for conducting an electric current from or to a conductor track of the conductor track arrangement (16) of the circuit carrier (12), and a current measuring resistor (22) via which the bus bar (20) and the conductor track in question are electrically connected to one another in order to enable the current to be measured by tapping a measuring voltage which drops across the current measuring resistor (22), characterized in that the bus bar (20) has a surface portion (26) located at a vertical distance (d) from a flat side (24) of the conductor track arrangement (16) and oriented substantially parallel to this flat side (24), and in that the current measuring resistor (22) is interposed between said surface portion (26) of the bus bar (20) and a surface portion (28) of the respective conductor track of the conductor track arrangement (16) and is physically and electrically connected to these surface portions (26, 28).

In some embodiments, the bus bar (20) is designed as a profiled part made of metal material.

In some embodiments, a cross-section of the bus bar (20) has an area of at least 20 mm 2 or at least 50 mm 2 .

In some embodiments, the vertical distance (d) of the surface portion (26) of the bus bar (20) from the flat side (24) of the conductor track arrangement (16) is at least 0.5 mm or 1 mm, and is at most 10 mm or at most 5 mm.

In some embodiments, the current measuring resistor (22) is plate-shaped with a uniform cross-section when viewed in the vertical direction.

In some embodiments, a vertical end located on the side of the bus bar (20) and/or a vertical end of the current measuring resistor (22) located on the side of the conductor track in question is provided with a single-ply or multi-ply connection layer (30, 32).

In some embodiments, the physical and electrical connection of the current measuring resistor (22) on the side of the bus bar (20) and/or on the side of the conductor track in question is realized by means of soldering, sintering, welding, riveting, screwing or bonding a respective vertical end of the current measuring resistor (22) to the respective surface portion (26, 28).

In some embodiments, the physical and electrical connection of the current measuring resistor (22) on the side of the bus bar (20) and/or on the side of the respective conductor track is realized by using a sinter layer (32) between a respective vertical end of the current measuring resistor (22) and the respective surface portion (26, 28).

In some embodiments, the circuit arrangement (10) has a plurality of current measuring resistors (22a-1, 22a-2) ; wherein the bus bar (20) has the same plurality of bus bar branches each having a surface portion (26a-1, 26a-2) ; the conductor track in question has the same number of surface portions (28a-1, 28a-2) ; wherein each of the current measuring resistors (22a-1, 22a-2) is respectively interposed between the respective surface portion (26a-1, 26a-2) of the respective bus bar branches of the bus bar (20a) and a respective surface portion (28a-1, 28a-2) of the respective conductor track and is physically and electrically connected to the respective surface portion (26a-1, 26a-2) of the respective bus bar branches of the bus bar (20a) and the respective surface portion (28a-1, 28a-2) of the respective conductor track.

As another example, some embodiments include a method for arranging a current measuring resistor (22) in a power-electronic circuit arrangement (10), comprising: a) providing a plate-shaped circuit carrier (12) which has an electrically insulating substrate (14) and a conductor track arrangement (16) on a flat side (15) of the substrate (14), b) providing one or more power-electronic components (18) and electrically contacting them by means of the conductor track arrangement (16), c) providing and arranging a bus bar (20) provided for conducting an electric current from or to a conductor track of the conductor track arrangement (16) in such a way that this bus bar has a surface portion (26) located at a vertical distance (d) from a flat side (24) of the conductor track arrangement (16) and oriented substantially parallel to this flat side (24), and d) providing a current measuring resistor (22) and electrically connecting the bus bar (20) and the respective conductor track of the conductor track arrangement (16) via the current measuring resistor (22), comprising physically and electrically connecting the surface portion (26) of the bus bar (20) to a first vertical end of the current measuring resistor (22) and physically and electrically connecting a second vertical end of the current measuring resistor (22) opposite the first vertical end of the current measuring resistor (22) to a surface portion (28) of the respective conductor track of the conductor track arrangement (16).

### BRIEF DESCRIPTION OF THE DRAWINGS

The teachings herein are described in more detail below based on exemplary embodiments with reference to the accompanying drawings, in which, in each case schematically:

FIG. 1 shows a side view of an example circuit arrangement incorporating teachings of the present disclosure;

FIG. 2 shows a plan view of the circuit arrangement of FIG. 1;

FIG. 3 shows a circuit diagram of the circuit arrangement of FIG. 1;

FIG. 4 shows a plan view of an example circuit arrangement incorporating teachings of the present disclosure; and

FIG. 5 shows a circuit diagram of the circuit arrangement of FIG. 4.

### DETAILED DESCRIPTION

An example power-electronic circuit arrangement incorporating teachings of the present disclosure includes: the bus bar has a surface portion located at a vertical distance from a flat side of the conductor track arrangement and oriented substantially parallel to this flat side, and the current measuring resistor is interposed between said surface portion of the bus bar and a surface portion of the respective conductor track of the conductor track arrangement and is physically and electrically connected to or contacted to these surface portions. This makes it possible to achieve a good electrical and thermal connection of the current measuring resistor with a small installation space and low-cost assembly and connection technology.

The term “power-electronic” is to be interpreted broadly and, in the context of the present disclosure, means that a comparatively high electrical power is involved for electronic devices, which is generated or controlled by the circuit arrangement during operation of the latter, for example. This is usually the case, for example, if the circuit arrangement is not intended for the generation and/or control of electrical energy for pure data processing, but this energy is used to supply “electrical consumers”. The main focus here is on loads with a power requirement of more than 100 W, in particular more than 1 kw.

In this context, the term “bus bar” means that a current flowing via the bus bar during operation is intended for the purpose of transmitting electrical energy which is not purely for the purpose of data transmission, wherein this again includes, for example, in particular those applications in which values of more than 100 W, in particular more than 1 kw, of electrical power are achieved during operation of the circuit arrangement, which is transmitted via the bus bar.

In the context of the disclosure, the term “vertical” is usually intended to mean the direction “orthogonal to the plate plane” of the plate-shaped circuit carrier.

In some embodiments, the bus bar of the circuit arrangement is intended to conduct a current from or to the conductor track (whether direct current or alternating current) during operation of the circuit arrangement, the current strength of which can assume values of more than 100 A, in particular more than 250 A.

In some embodiments, this current strength is at least 500 A. A concrete example of this is the use or configuration of the circuit arrangement as an inverter (or as a part of an inverter) for the pulsed energization of an electric machine, in particular, for example, an electric motor in an electric or hybrid vehicle.

In this application, the bus bar can represent an electrical line connection or at least a portion of such a line connection, via which a phase current of a multi-phase energized electrical machine is conducted.

In some embodiments, the bus bar is designed as a profiled part made of metal material, in particular, for example, copper or a copper alloy (e.g., so-called technical copper). This advantageously takes into account the fact that preferred uses of the circuit arrangement within the scope of the invention require a comparatively high current strength of a current flowing through the bus bar.

In some embodiments, a cross-section of the bus bar (e.g., profile part) has an area of at least 20 mm 2, in particular at least 50 mm2.

In some embodiments, a cross-section of the bus bar has an at least approximately rectangular or square shape. Alternatively, this cross-section can be U-shaped or L-shaped, for example.

In some embodiments, the vertical distance of the surface portion of the bus bar from the flat side of the conductor track arrangement is at least 0.5 mm, in particular 1 mm, and/or a maximum of 10 mm, in particular a maximum of 5 mm. Such a design may be advantageous for achieving a compact arrangement with small installation space requirements.

In some embodiments, the current measuring resistor, which can also be referred to as a “shunt” in terms of its function, is plate-shaped, in particular with a uniform cross-section when viewed vertically. The term “plate-shaped” is used here to express the fact that the current measuring resistor has a transverse extent, i.e., extent parallel to the plane of the circuit carrier (and orthogonal to the direction of current flow in the current measuring resistor), which is greater than its vertical extent (“plate height”), i.e., extent orthogonal to the plane of the circuit carrier (and parallel to the direction of current flow in the current measuring resistor).

The transverse dimension (or e.g., a minimum transverse dimension) of the plate shape can be larger than its vertical dimension (height) by a factor of, e. g., at least 1.5, in particular at least 2. Such dimensions can contribute to a low overall height and a good electrical and thermal connection of the current measuring resistor.

The cross-section of the current measuring resistor, e.g., plate-shaped current measuring resistor, can have a polygonal shape, e.g., rectangular or square. Alternatively, the shape of the cross-section can also be round, in particular circular, for example. With a uniform cross-section in the vertical direction, the current measuring resistor is then, e. g., cuboidal or, e.g., cylindrical.

As far as the material of the current measuring resistor is concerned, materials known from the prior art can be used for this purpose. Examples of this are the materials offered commercially under the trade names “Manganin”, “Konstantan” and “Zeranin” or materials with similar properties. These are special “resistance materials” (e.g., metal alloys) that have a low specific electrical resistance that is only slightly dependent on temperature. The advantage of this is that the voltage drop measured at the current measuring resistor for the purpose of current measurement, i.e., the measuring voltage, is at most only slightly affected by any temperature fluctuations of the current measuring resistor.

Such temperature fluctuations of the current measuring resistor can be caused in particular in mobile applications (e.g., power electronics in a vehicle, e.g., inverters), e.g., by fluctuations in the ambient temperature. In addition, the current flowing through the current measuring resistor generates heat loss, which leads to corresponding temperature fluctuations in the current measuring resistor if the current is not constant over time. The latter effect may be reduced in the context of the invention by a low thermal resistance between the current measuring resistor and its surroundings.

The tapping of the measuring voltage dropping at the current measuring resistor or a tapping of measurement potentials required for this purpose can be realized, for example, by means of bonding wires, one end of each of which is bonded to the bus bar or the conductor track, in each case in the vicinity of the current measuring resistor, wherein the respective other ends of the bonding wires can in particular be bonded to a conductor track of a further circuit carrier (i.e., separate from the circuit carrier carrying the power electronics), which carries corresponding evaluation electronics.

In some embodiments, a vertical end of the current measuring resistor located on the side of the bus bar and/or on the side of the conductor track is provided with a single- or multi-ply connection layer. The advantage of such a connection layer made of a material that differs from the “core material” (resistor material) of the current measuring resistor is that it can improve the mechanical and thus also the electrical and thermal connection of the relevant vertical end of the current measuring resistor to the relevant surface portion (the bus bar or the conductor track in question). The material of each connection layer or, in the case of a multi-ply connection layer, the materials of the individual layers can be adapted or optimized to the specific application, specifically depending on
which materials are to be connected to each other via the connection layer (e.g., copper alloy of the bus bar with resistance material of the current measuring resistor, and copper alloy of the conductor track in question with resistance material of the current measuring resistor), and
how (connection technique) these materials are to be connected.

In some embodiments, the connection of the current measuring resistor on the side of the bus bar and/or on the side of the relevant conductor track is realized by soldering a relevant vertical end of the current measuring resistor to the relevant surface portion. If necessary, the solderability or quality of the soldering can be improved in this case by selecting an appropriate connection layer. The current measuring resistor can also be connected to the bus bar and/or the conductor track, e. g., by means of welding. Another possibility for realizing such a connection is the use of bonding (with electrically conductive adhesive). In the latter cases, the weldability or bondability can also be improved by providing an appropriately selected connection layer.

In some embodiments, the connection of the current measuring resistor on the side of the bus bar and/or on the side of the conductor track is realized by using a sintered layer between a respective vertical end of the current measuring resistor and the respective surface portion.

In some embodiments, the the connection of the current measuring resistor on the side of the bus bar is realized by means of welding, in particular e.g., ultrasonic welding, of the relevant vertical end of the current measuring resistor to the surface portion of the bus bar, wherein an appropriately selected connection layer may be provided at this end to improve the weldability, and the electrical connection of the current measuring resistor on the side of the conductor track is realized by means of a sintered layer between the respective vertical end of the current measuring resistor and the surface portion of the conductor track.

Some embodiments include a method for arranging a current measuring resistor in a power-electronic circuit arrangement comprising:
a) providing a plate-shaped circuit carrier which has an electrically insulating substrate and conductor track arrangement on a flat side of the substrate,
b) providing one or more power-electronic components and electrically contacting them by means of the conductor track arrangement,
c) providing and arranging a bus bar provided for conducting an electric current from or to a conductor track of the conductor track arrangement in such a way that the bus bar has a surface portion located at a vertical distance from a flat side of the conductor track arrangement and oriented substantially parallel to this flat side, and
d) providing a current measuring resistor and electrically connecting the bus bar and the respective conductor track of the conductor track arrangement to each other via the current measuring resistor, comprising connecting the surface portion of the bus bar to a first vertical end of the current measuring resistor and connecting a second vertical end of the current measuring resistor opposite the first vertical end of the current measuring resistor to a surface portion of the respective conductor track of the conductor track arrangement.

With regard to the implementation of step d), it should be noted that different variants are possible.

In some embodiments, the connection of the bus bar to the relevant, i.e., first vertical end of the current measuring resistor is already carried out before the bus bar is arranged with respect to the circuit carrier (i.e., at a vertical distance from a flat side of the conductor track arrangement).

In some embodiments, the connection of the second vertical end of the current measuring resistor to the conductor track of the conductor track arrangement is already carried out before the bus bar is arranged in relation to the circuit carrier. For example, this connection of the current measuring resistor to the conductor track arrangement can be carried out together with the step of electrically contacting the power-electronic component(s) by means of the conductor track arrangement, i.e., as part of populating the circuit carrier with components.

In some embodiments, both the connection of the bus bar to the current measuring resistor and the connection of the current measuring resistor to the conductor track are only carried out after the bus bar has already been arranged and fastened in relation to the circuit carrier. In this case, the current measuring resistor can be inserted and connected (e.g., by soldering, welding, etc.) in the installation location provided between the bus bar and the conductor track.

The embodiments and special designs described here for the circuit arrangement described herein may, individually or in any combination, also be provided in the same way as embodiments or special designs of the methods, and vice versa. The design of the plate-shaped circuit carrier can be based on designs known from the prior art. For example, the circuit carrier or its electrically insulating substrate can have a rectangular format, wherein with regard to the thermal requirements of power-electronic circuit arrangements, a substrate made of a ceramic material such as, for example, based on aluminum nitride (AIN) or, for example, based on aluminum oxide (Al2O3) may be advantageous.

If a conductor track arrangement is only provided on one of the two flat sides of the substrate, the other flat side (rear side) of the substrate can be connected to a heat sink for the purpose of heat dissipation, e.g., bonded to the heat sink or soldered to the heat sink via a layer, e.g., metal layer, provided on the rear side. In some embodiments, such a heat sink has a cooling channel through which a cooling medium such as cooling water can flow during operation of the circuit arrangement.

In some embodiments, the power-electronic component(s) may be power semiconductor components such as diodes, transistors (e.g., MOS-FETS), thyristors, etc. In particular, semiconductor components manufactured using SiC (silicon carbide) technology, for example, can be provided at this point. In addition, depending on the application, other components and in particular passive components such as coils, capacitors etc. can be electrically contacted on the flat side of f the substrate by means of the conductor track arrangement.

The bus bar for conducting the electric current from or to the relevant conductor track of the conductor track arrangement can be surrounded or encased (e.g., overmolded) at least in portions by plastics material, e. g., the material of a housing or a housing part of the circuit arrangement.

One or more electrical connection devices such as plug connectors (sockets) etc. can be provided on a housing of the circuit arrangement, via which the circuit arrangement is integrated into a relevant electrical environment. The connection device can have an electrical contact that is electrically connected to the bus bar in order to conduct the current through the housing to the bus bar or from the bus bar out of the housing. Depending on the design of the circuit arrangement, further such contacts may be provided, for example to transmit supply potentials (supply voltage) or electrical data signals.

In some embodiments, the arrangement provides a multi-phase, in particular e.g., three-phase inverter, in which accordingly several (e.g., three) bus bars are present, via which corresponding phase currents are output from the inverter to the relevant electrical device (e.g., three-phase electric drive machine).

In some embodiments, the circuit arrangement has a plate-shaped circuit carrier on which a conductor track arrangement and all components for forming the inverter are provided, wherein a corresponding plurality of bus bars (e. g., three) are also provided for conducting the individual phase currents from or to respective (different) conductor tracks of the conductor track arrangement. Depending on requirements, one or more current measuring resistors can be integrated in the manner already described in order to measure a respective phase current with each such current measuring resistor. The power electronics of the inverter can be advantageously manufactured using SiC technology, for example.

In some embodiments, the circuit arrangement has a plurality of (e.g., three) plate-shaped circuit carriers, on each of which a conductor track arrangement and the components for forming only a respective inverter part (e.g., half-bridge for outputting a phase current) are provided, wherein a bus bar for conducting the respective phase current from or to a respective conductor track of the conductor track arrangement is further provided in each case. Depending on requirements, one or more current measuring resistors can be integrated in the manner already described in order to measure a respective phase current with each such current measuring resistor. The multiple circuit carriers and bus bars can be accommodated in a common housing.

Furthermore, the circuit arrangement may, for example, have a plurality of current measuring resistors. In this case, the bus bar can have the same plurality of bus bar branches—i.e., branch-shaped, tongue-shaped or arm-shaped (end) portions of the bus bar that protrude from the main portion of the bus bar and are formed in one piece with the main portion—each with a surface portion. Similarly, the relevant conductor track of the conductor track arrangement can have the same number of surface portions. Each of the current measuring resistors can be interposed between the respective surface portion of the respective bus bar branches of the bus bar and a respective surface portion of the respective conductor track and can be physically and electrically connected or contacted to the respective surface portion of the respective bus bar branches of the bus bar and the respective surface portion of the respective conductor track.

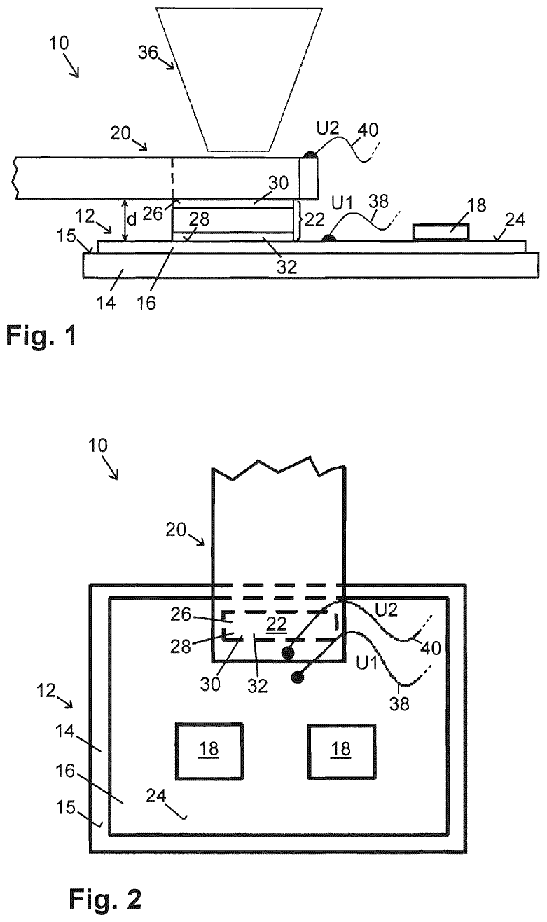

FIGS. 1 and 2 show an exemplary embodiment of a power-electronic circuit arrangement 10 incorporating teachings of the present disclosure and including:
a plate-shaped circuit carrier 12, which has an electrically insulating substrate 14 and, on a flat side 15 of the substrate 14, a conductor track arrangement 16 and one or more power-electronic components 18 electrically contacted by means of the conductor track arrangement 16,
a bus bar 20 for conducting an electric current from or to a conductor track of the conductor track arrangement 16 of the circuit carrier 12, and
a current measuring resistor (“shunt”) 22 via which the bus bar 20 and the relevant conductor track are electrically connected to one another in order to enable the current to be measured by tapping a measuring voltage which drops across the current measuring resistor 22.

In the example shown, it is assumed that the circuit arrangement 10 is designed as part of an inverter for the pulsed energization of a three-phase energized electric motor in an electric or hybrid vehicle, wherein the bus bar 20 of the circuit arrangement 10 is intended to carry a pulsed current (e.g., PWM phase current) during operation of the circuit arrangement 10, the current strength of which can assume values of more than 250 A. The bus bar 20 represents a portion of an electrical line connection via which one of the three phase currents of the electric motor is routed.

In the example, the electrically insulating substrate 14 is formed from a ceramic material based on aluminum nitride (AlN), wherein the other flat side (rear side) of the substrate 14 facing away from the components 18 is connected to a (not shown) heat sink (e. g., made of aluminum or copper material) for the purpose of heat dissipation, e.g., bonded or soldered to the heat sink via a layer provided on the rear side, e.g., a metal layer.

The bus bar 20 has a surface portion 26 located at a vertical distance “d” to a flat side 24 of the conductor track arrangement 16 and oriented parallel to this flat side 24, and that the current measuring resistor 22 is interposed between this surface portion 26 of the bus bar 20 and a surface portion 28 of a relevant conductor track of the conductor track arrangement 16 and is connected to these surface portions 26, 28. This enables a good electrical and thermal connection of the current measuring resistor 22 while at the same time using low-cost assembly and connection technology. The current flows through the current measuring resistor 22 in the vertical direction (orthogonal to the plane of the circuit carrier 12, as a “vertical shunt”), wherein the current measuring resistor 22 is in thermal contact not only with an adjacent portion of the bus bar 20, but also with the conductor track arrangement and thus with the substrate 14 of the circuit carrier 12, which can generally be cooled well, for example.

To ensure a sufficiently high current-carrying capacity in the example shown, the bus bar 20 is designed as a profiled part made of a copper alloy with a cross-sectional area of approx. 40 mm2.

In the example, the cross-section is rectangular (e.g., approx. 2 mm×20 mm), wherein said surface portion 26 of the bus bar 20, which is provided for connecting the current measuring resistor 22 and is oriented parallel to the flat side 24 of the conductor track arrangement 16, is provided on a long side of the rectangular cross-section. This enables a relatively large-area connection of the current measuring resistor 22 and also favors a compact design of the circuit arrangement 10 with relatively low vertical installation space requirements.

The vertical distance “d” between the surface portion 26 of the bus bar 20 and the flat side 24 of the conductor track arrangement 16 is approximately 2 mm in the example and also contributes advantageously to achieving a compact design.

In some embodiments, the vertical distance to the flat side of the conductor track arrangement to vary over the course of the bus bar, in particular to decrease towards one end of the bus bar at which said surface portion is provided. This can be advantageous, for example, with regard to a certain design-related desired further course of the bus bar.

In the example, the current measuring resistor 22 is plate-shaped, i.e., with a transverse dimension that is more or less significantly larger than the vertical dimension (height) of approx. 2 mm in the example. With a uniform rectangular cross-section of the current measuring resistor 22 when viewed vertically (see FIG. 2), the current measuring resistor 22 is cuboidal in this case.

In the example, the current measuring resistor 22 consists largely (e. g., more than 95%, in particular more than 98% of the volume) of a metal alloy which has a low specific electrical resistance (e.g., in the order of magnitude of about 100 to 10-1 Ω mm2), which is only slightly temperature-dependent, such as a material offered under the trade name “Manganin”, “Konstantan” or “Zeranin” or a material with similar properties.

To a certain extent, this material forms the functional core of the current measuring resistor 22, wherein in the example both a vertical end (top in FIG. 1) located on the side of the bus bar 20 and a vertical end (bottom in FIG. 1) located on the side of the relevant conductor track of the current measuring resistor 22 are provided with a respective connection layer 30, 32.

Each of the two connection layers 30, 32, for example, each formed in one or more plies and each formed from a material different from the “core material” (resistor material), ensures in the example a good mechanical, electrical and thermal connection of the relevant vertical end of the current measuring resistor 22 to the relevant surface portion 30 (the bus bar) or 32 (the conductor track).

The material of each connection layer 30, 32 or, in the case of a multi-ply connection layer, the materials of the individual layers can be selected to optimize the specific application. In the illustrated exemplary embodiment, it is assumed, for example, and must be taken into account when selecting the connection layers 30, 32, that a copper alloy of the bus bar 22 is to be connected to the resistance material (metal alloy) of the current measuring resistor 22 via the connection layer 30 and a further copper alloy (of the relevant conductor track) is to be connected to this resistance material of the current measuring resistor 22 via the connection layer 32.

In the example, it is provided that the connection on the side of the bus bar 20 is realized by means of ultrasonic welding, wherein the connection layer 30 is selected accordingly to improve the resulting welding quality, whereas the connection layer 32 is a sintered layer which is formed in a sintering process to connect the current measuring resistor 22 on the side of the conductor track.

A method for arranging the current measuring resistor 22 in the circuit arrangement 10 may include:
a) providing the plate-shaped circuit carrier 12, which has the electrically insulating substrate 14 and, on (at least) one flat side 15 of the substrate 14, a conductor track arrangement 16, which can comprise, for example, conductor tracks made of metal material (here, for example, copper material) in a conventional manner,
b) providing one or more power-electronic components 18, such as diodes, transistors (e.g., bipolar or FET), thyristors, coils, capacitors, etc., and electrically contacting these components by means of the conductive track arrangement 16, e.g., in a conventional manner by soldering component connections to the conductive track arrangement 16,
c) providing and arranging the bus bar 20 in such a way that it has the surface portion 26 located at a vertical distance d from the flat side 24 of the conductor track arrangement 16 and oriented at least approximately parallel to this flat side 24,
d) providing the current measuring resistor 22 and electrically connecting the bus bar 20 and the relevant conductor track of the conductor track arrangement 16 to one another via the current measuring resistor 22 by means of
d1) connecting the surface portion 26 of the bus bar 20 to a first (in FIG. 1 upper) vertical end of the current measuring resistor 22, in the example by means of welding to the connection layer 30, and
d2) connecting the opposite second (in FIG. 1 lower) vertical end of the current measuring resistor 22 to the surface portion 28 of the relevant conductor track of the conductor track arrangement 16, in the example by sintering a connection layer 32 arranged therebetween.

The above steps and their individual sub-steps do not necessarily have to be carried out in the specified order. Rather, there are numerous variants for the specific sequence.

In the example shown, for example, a variant is provided in which the second (in FIG. 1 lower) vertical end of the current measuring resistor 22 is connected to the conductor track of the conductor track arrangement 16 via the sintered layer 32, even before the power-electronic components 18 are soldered to the conductor track arrangement 16 and even before the bus bar 20 is arranged and fastened with respect to the circuit carrier 12. For the purpose of fastening the bus bar 20 in the arrangement shown in FIG. 1, it can, for example, be surrounded or encased in portions by plastics material of a housing (not shown) or a housing part of the circuit arrangement 10.

To connect the second (in FIG. 1 lower) vertical end of the current measuring resistor 22, the connection layer 32 shown in FIG. 1 can first be arranged as a sintered blank and then sintered by suitable temperature control and thereby firmly connected to the adjacent materials, i.e., on the one hand to the material of the conductor track and on the other hand to the resistor material. As an alternative to a solid (pressed) sintered blank, the use of a paste-like agent containing the corresponding sintered particles (e.g., “sinter paste”), which is applied to the second vertical end and/or the surface portion 28 of the conductor track arrangement 16 before the current measuring resistor 22 is arranged, can also be considered at this point.

For ultrasonic welding of the first (upper in FIG. 1) vertical end of the current measuring resistor 22 (connection layer 30), a sonotrode 36 can be placed on the bus bar 20 on its side facing away from the connection layer 30, as shown in FIG. 1.

Quite generally, in the methods for arranging a current measuring resistor described herein, the resistor can already be provided with a respective connection layer, such as the connection layers 30, 32 in the example, as part of its manufacture (e.g., metallization layer) before it is used in the method. In some embodiments, at least one such connection layer can also be formed within the scope of the method.

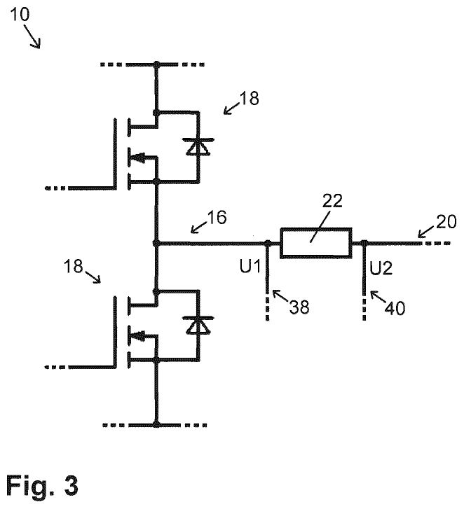

FIG. 3 shows a circuit diagram of some key components of the circuit arrangement 10 shown in FIGS. 1 and 2, which in the example, as already mentioned, forms part of an inverter for a three-phase energized electric motor. In the example shown, this is a half-bridge formed from two MOS-FETs (components 18) for generating a phase current, which is output via the current measuring resistor 22 and the current bar 20 connected to it. During operation of the inverter, the three phase currents in question flow to an assigned phase connection of the electric motor via an electrical connection (not shown) connected to the circuit arrangement 10 (e. g., electrical plug connection(s), cable harness, etc.). The bus bar 20 therefore represents a portion of an electrical line connection via which the relevant phase current of the electric motor is conducted.

Since this current also flows through the current measuring resistor 22, the current intensity can be determined by tapping and evaluating a measuring voltage that drops across the current measuring resistor 22. For this current measurement, as shown in FIGS. 1 to 3, two potentials U1 and U2 are tapped and fed to an evaluation circuit (not shown) of the circuit arrangement 10 to determine the potential difference (=tapped measuring voltage) “U2-U1” and thus determine the (proportional) current strength.

It should be noted at this point that the evaluation circuit may take into account one or more other measured variables, such as a measured variable representative of the temperature of the current measuring resistor 22, when determining the current strength. The evaluation circuit as well as, for example, a control circuit for controlling the half-bridge (power-electronic components) shown in FIG. 3 can be formed on a separate circuit carrier.

As shown in FIGS. 1 and 2, the tapping of the measuring voltage U2-U1 or the tapping of the individual measurement potentials U1, U2 is realized by means of bonding wires 38 (for U1) and 40 (for U2), via which the measurement potentials U1, U2 are transmitted to the evaluation circuit. The bonding wires 38, 40 can be made of gold, silver, copper or aluminum or a corresponding metal alloy, for example, in a manner known per se.

For a current measurement that is as accurate and reproducible as possible (i.e., less dependent on manufacturing tolerances), it is advantageous if the bonding wires 38, 40 are not bonded directly to the material of the vertical ends of the current measuring resistor 22 (bonding points), but instead these bonding points are provided on the material of the adjacent components, i.e., conductor track (for U1) or bus bar (for U2), as can be seen in the exemplary embodiment shown.

For the specific arrangement of the bonding point on the conductor track, it is usually also advantageous if this bonding point is provided along the conductor track on a portion of the conductor track through which the current does not flow or if this bonding point, with respect to the current measuring resistor 22, is therefore located on a side of the current measuring resistor 22 facing away from the portion of the conductor track through which the current flows.

The same applies to the specific arrangement of the bonding point on the bus bar 20. In other words, it is usually advantageous here if the bonding point is provided on a portion of the bus bar 20 along the bus bar 20 through which the current does not flow or if this bonding point, with respect to the current measuring resistor 22, is therefore located on a side of the current measuring resistor 22 facing away from the portion of the bus bar 20 through which the current flows. As can be seen from FIGS. 1 and 2, in this example the bus bar 20 is slightly extended beyond the region of the current measuring resistor 22, so that the bonding wire 40 can be connected to this “protruding” (non-current-carrying) portion of the bus bar 20.

To create the three-phase inverter, three circuit arrangements 10 of the type shown in FIGS. 1 to 3 are combined together with shared control electronics (for controlling the MOS-FETs, e.g., according to a PWM control scheme) and, if necessary, the aforementioned evaluation circuit. In this case, the inverter comprises three plate-shaped circuit carriers 10, on each of which a conductor track arrangement 16 and the components 18 for forming only one respective inverter part (half-bridge for outputting a phase current) and, furthermore, only one bus bar 20 for conducting the respective phase current are provided.

Depending on requirements, one or more current measuring resistors 22 can be integrated in such an inverter in the manner already described in order to measure the respective phase current with each such current measuring resistor 22. The multiple circuit carriers 12 and bus bars 22 can be accommodated in a common housing.

In the following description of a further exemplary embodiment, the same reference signs are used for components having the same effect. In principle, only the differences to the exemplary embodiment already described are discussed and, in addition, explicit reference is hereby made to the above description of the preceding exemplary embodiment.

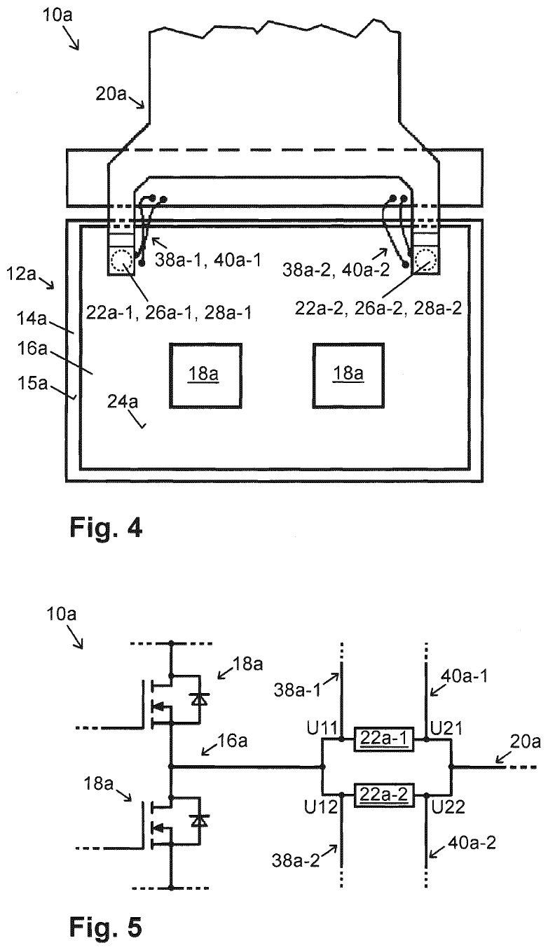

FIGS. 4 and 5 show a further exemplary embodiment of a power-electronic circuit arrangement 10a, in representations corresponding to FIGS. 2 and 3. In contrast to the exemplary embodiment of FIG. 1 to 3, a bus bar 20a of the circuit arrangement 10a according to this further example has a branching into a plurality of bus bar branches, two in the example shown, such that the bus bar 20a has respective surface portions 26a-1, 26a-2 at the ends of these bus bar branches, which are each located at a vertical distance from a flat side 24a of a conductor track arrangement 16a and are oriented parallel to this flat side 24a.

In addition, the circuit arrangement 10a has two current measuring resistors 22a-1, 22a-2 corresponding to the number of bus bar branches, via which the respective bus bar branches of the bus bar 20a are electrically connected to respective conductor tracks of the conductor track arrangement 16a in order to enable measurements of the currents flowing via the bus bar branches by tapping the (in the example two) measuring voltages U21-U11 and U22-U12 dropping across the current measuring resistors 22a-1, 22a-2.

Analogously to the exemplary embodiment of FIGS. 1 to 3 already described above, the circuit arrangement 10a according to this further example also provides that each of the current measuring resistors 22a-1, 22a-2 is interposed between the respective surface portion 26a-1, 26a-2 of the respective bus bar branch of the bus bar 20a and a respective surface portion 28a-1, 28a-2 of a respective conductor track of the conductor track arrangement 16a and is connected to these surface portions 26a-1 or 26a-2, 28a-1 or 28a-2. These connections of the current measuring resistors 22a-1, 22a-2 can each be provided in such a way or can be accomplished in the context of a method for arranging several (e.g., two) current measuring resistors in a power-electronic circuit arrangement, as has already been described with reference to the exemplary embodiment of FIGS. 1 to 3.

In this further exemplary embodiment, the two potential differences U21-U11 and U22-U12 or the two corresponding measurement potential pairs U11, U21 and U12, U22 can again be transmitted by means of bonding wires 38a-1, 40a-1, 38a-2, 40a-2 to an evaluation circuit of the circuit arrangement 10a, which can thus determine the current intensity of the electric current flowing through the bus bar 20a (as the sum of the two partial currents flowing through the individual bus bar branches). In this example, the evaluation circuit (not shown) is advantageously arranged on a separate circuit carrier (less expensive than the circuit carrier 12a with ceramic substrate 14a).

Each of the current measuring resistors 22a-1, 22a-2 is loaded to a lesser extent and can therefore be dimensioned smaller, for example, than would be the case if only a single current measuring resistor were used as in the first example (FIGS. 1 to 3). In addition, heat loss generated by the current measurement can generally be dissipated even better due to the spatial distribution of the multiple current measuring resistors 22a-1, 22a-2.

A further difference between the circuit arrangement 10a and the exemplary embodiment of FIGS. 1 to 3 is that, viewed over the course of the bus bar 20a, a vertical distance between the bus bar 20a and the flat side 24a of the conductor track arrangement 16a decreases towards the ends of the bus bar branches. In the example, the bus bar 20a, for example in the area of the two bus bar branches, has correspondingly angled portions.

A further difference between the circuit arrangement 10a and the exemplary embodiment already described is that a cross-section of each of the current measuring resistors 22a-1, 22a-2 is circular. This cross-section, which is uniform in the vertical direction in the example, results in a cylindrical shape for each current measuring resistor 22a-1, 22a-2.

### LIST OF REFERENCE SIGNS

10 Circuit arrangement
12 Circuit carrier
14 Substrate
15 Flat side of the substrate
16 Conductor arrangement
18 Component(s)
20 Bus bar
d Vertical distance
22 Current measuring resistor (shunt)
U1 Measurement potential
U2 Measurement potential
24 Flat side of the conductor track arrangement
26 Surface portion of the bus bar
28 Surface portion of the conductor track
30 Connection layer
32 Connection layer
36 Sonotrode
38 Bonding wire
40 Bonding wire

What is claimed is:

1. A power-electronic circuit arrangement: comprising:
a plate-shaped circuit carrier with an electrically insulating substrate and a conductor track arrangement—on a side of substrate, and one or more power-electronic components electrically contacted by the conductor track arrangement;
a bus bar to conduct an electric current from or to a conductor track of the conductor track arrangement; and
a current measuring resistor connecting the bus bar and the conductor track to enable the current to be measured by tapping a measuring voltage dropping across the current measuring resistor;
wherein the bus bar has a surface portion located at a vertical distance from a flat side of the conductor track arrangement and oriented substantially parallel to the flat side; and
the current measuring resistor is interposed between said surface portion of the bus bar and a surface portion of the conductor track of the conductor track arrangement and is physically and electrically connected to these surface portions.

2. The circuit arrangement as claimed in claim 1, wherein the bus bar comprises of a profiled piece of metal.

3. The circuit arrangement as claimed in claim 1, wherein a cross-section of the bus bar has an area of at least 20 mm2.

4. The circuit arrangement as claimed in claim 1 wherein the vertical distance is at least 0.5 mm, and is at most 10 mm.

5. The circuit arrangement as claimed in claim 1, wherein the current measuring resistor is plate-shaped with a uniform cross-section when viewed in the vertical direction.

6. The circuit arrangement as claimed in claim 1, wherein a vertical end on the side of the bus bar and/or a vertical end of the current measuring resistor located on the side of the conductor track includes a connection layer.

7. The circuit arrangement as claimed in claim 1, wherein the physical and electrical connection of the current measuring resistor on the side of the bus bar and/or on the side of the conductor track includes connection made by soldering, sintering, welding, riveting, screwing, or bonding a respective vertical end of the current measuring resistor to the respective surface portion.

8. The circuit arrangement as claimed in claim 1, wherein the physical and electrical connection of the current measuring resistor on the side of the bus bar and/or on the side of the respective conductor track includes a sinter layer between a respective vertical end of the current measuring resistor and the respective surface portion.

9. A circuit arrangement claimed in claim 1, wherein
the circuit arrangement includes a set of current measuring resistors;
the bus bar has a set of bus bar branches each corresponding to one of the set of current measuring resistors and each having respective surface portion;
the conductor track has a set of surface portions;
each of the current measuring resistors is respectively interposed between the respective surface portion of the respective bus bar branches of the bus bar and a respective surface portion of the conductor track and is physically and electrically connected to the respective surface portion of the respective bus bar branches of the bus bar and the respective surface portion of the conductor track.

10. A method for arranging a current measuring resistor in a power-electronic circuit arrangement, the method comprising:
providing a plate-shaped circuit carrier having an electrically insulating substrate and a conductor track arrangement on a side of the substrate;
contacting one or more power-electronic components using the conductor track arrangement;
arranging a bus bar for conducting an electric current from or to a conductor track of the conductor track arrangement in such a way that this bus bar has a surface portion located at a vertical distance from a flat side of the conductor track arrangement and oriented substantially parallel to the flat side;
connecting a current measuring resistor between the bus bar and the conductor track, comprising physically and electrically connecting the surface portion of the bus bar to a first vertical end of the current measuring resistor and physically and electrically connecting a second vertical end of the current measuring resistor opposite the first vertical end of the current measuring resistor to a surface portion of the conductor track.
